(19) United States
(12) Patent Application Publication
(10) Pub. No.: US 2025/0346834 A1
(43) Pub. Date: Nov. 13, 2025

(54) TREATMENT LIQUID, CLEANING METHOD FOR OBJECT TO BE TREATED, AND METHOD FOR MANUFACTURING ELECTRONIC DEVICE

(71) Applicant: FUJIFLM CORPORATION, Tokyo (JP)

(72) Inventors: Shimpei Yamada, Shizuoka (JP); Tetsuya Kamimura, Shizuoka (JP)

(21) Appl. No.: 19/277,755

(22) Filed: Jul. 23, 2025

Related U.S. Application Data
(63) Continuation of application No. PCT/JP2024/003404, filed on Feb. 2, 2024.

(30) Foreign Application Priority Data
Mar. 15, 2023 (JP) 2023-040647

(51) Int. Cl. C11D 7/34; C11D 7/26; C11D 7/32

(52) U.S. Cl. CPC C11D 7/34; C11D 7/265; C11D 7/3245; C11D 2111/22

(57) ABSTRACT

The present invention provides a treatment liquid which is excellent in anticorrosion properties for molybdenum and excellent in defect removability on an object to be treated, in a case of being applied to cleaning of the object to be treated, which contains a molybdenum-containing substance and has been subjected to chemical mechanical polishing treatment. In addition, the present invention provides a cleaning method for an object to be treated, using the above-described treatment liquid, and a method for manufacturing an electronic device. The treatment liquid of the present invention is used for cleaning an object to be treated, which contains a molybdenum-containing substance and has been subjected to chemical mechanical polishing, the treatment liquid containing a polymer having a sulfonic acid group or a salt thereof, and water.

### CROSS-REFERENCE TO RELATED APPLICATIONS

This application is a Continuation of PCT International Application No. PCT/JP2024/003404 filed on Feb. 2, 2024, which claims priority under 35 U.S.C. § 119(a) to Japanese Patent Application No. 2023-040647 filed on Mar. 15, 2023. The above applications are hereby expressly incorporated by reference, in their entirety, into the present application.

### BACKGROUND OF THE INVENTION

### 1. Field of the Invention

The present invention relates to a treatment liquid, a cleaning method for an object to be treated, and a method for manufacturing an electronic device.

### 2. Description of the Related Art

In the field of semiconductors, with remarkable increase in integration and performance, even a very small amount of impurities (contamination) and/or attachments (particles) has a great influence on the performance of an apparatus and eventually the yield of a product.

In each manufacturing step of a semiconductor element, various contaminations and particles (hereinafter, also referred to as residues) may be generated. For example, as one process in manufacturing of the semiconductor element, a chemical mechanical polishing (CMP) treatment in which a surface of a semiconductor substrate having a metal wire film, a barrier metal, an insulating film, or the like is flattened using a polishing slurry containing abrasive particles (for example, silica and alumina) or the like may be carried out. In the chemical mechanical polishing treatment, the abrasive particles to be used in the chemical mechanical polishing treatment, a polished wiring line metal film, and/or a metal component derived from the barrier metal or the like easily remain on the surface of the semiconductor substrate after polishing. Therefore, after the chemical mechanical polishing treatment, a step of removing these residues using a treatment liquid is generally performed.

As the treatment liquid as described above, for example, JP2012-094852A discloses a substrate cleaning liquid for a semiconductor device, which contains (A) an organic acid, (B) a sulfonic acid-type anionic surfactant, (C) at least one polymer coagulating agent selected from polyvinylpyrrolidone and a polyethylene oxide-polypropylene oxide block copolymer, and (D) water.

### SUMMARY OF THE INVENTION

In a case where the present inventors prepare a treatment liquid with reference to the content disclosed in JP2012-094852A, and apply the treatment liquid to cleaning of an object to be treated, which contains a molybdenum-containing substance and has been subjected to the CMP treatment, it is found that it is difficult to achieve both anticorrosion properties for molybdenum and defect removability.

Here, the “anticorrosion properties for molybdenum” refers to a performance in which corrosion of molybdenum by the cleaning liquid is suppressed. As the corrosion of molybdenum is suppressed, the anticorrosion properties are excellent. In addition, the “defect removability” refers to a performance that indicate a degree to which defects such as metal residues derived from a polishing liquid used for the CMP treatment and an object to be treated (for example, wiring line on a semiconductor substrate) remain on the object to be treated in a case where the object to be treated, which contains a molybdenum-containing substance, is subjected to the CMP treatment using a polishing liquid and then brought into contact with the treatment liquid. As the number of defects is small, the defect removability is excellent.

Therefore, an object of the present invention is to provide a treatment liquid which is excellent in anticorrosion properties for molybdenum and excellent in defect removability on an object to be treated, in a case of being applied to cleaning of the object to be treated, which contains a molybdenum-containing substance and has been subjected to a chemical mechanical polishing treatment.

Another object of the present invention is to provide a cleaning method for an object to be treated, using the above-described treatment liquid, and a method for manufacturing an electronic device.

The present inventors have completed the present invention as a result of intensive studies to solve the above-described problems. That is, the present inventors have found that the above-described objects can be achieved by the following configuration.

[1] A treatment liquid used for cleaning an object to be treated, which contains a molybdenum-containing substance and has been subjected to chemical mechanical polishing, the treatment liquid comprising:
a polymer having a sulfonic acid group or a salt thereof; and water.

[2] The treatment liquid according to [1],
in which the polymer further has a carboxy group or a salt thereof.

[3] The treatment liquid according to [2],
in which the polymer contains a repeating unit having a sulfonic acid group or a salt thereof and a repeating unit having a carboxy group or a salt thereof, and
a molar ratio C2/C1 of a content C2 of the repeating unit having a carboxy group or a salt thereof to a content C1 of the repeating unit having a sulfonic acid group or a salt thereof is 95/5 to 1/99.

[4] The treatment liquid according to any one of [1] to [3],
in which a weight-average molecular weight of the polymer is 1,500 to 100,000.

[5] The treatment liquid according to any one of [1] to [4], further comprising:
an organic acid having a hydroxy group and a carboxy group.

[6] The treatment liquid according to [5],
in which a mass ratio of a content of the organic acid to a content of the polymer is 0.010 to 200.

[7] The treatment liquid according to any one of [1] to [6], further comprising:
an amino acid.

[8] The treatment liquid according to [7],
in which a mass ratio of a content of the amino acid to a content of the polymer is 0.010 to 200.

[9] The treatment liquid according to any one of [1] to [8],
in which a content of sodium atoms is 1 ppm by mass or less with respect to a total mass of the treatment liquid.

[10] The treatment liquid according to any one of [1] to [9],
in which a pH is 3.0 to 9.0.

[11] A cleaning method for an object to be treated, comprising:
a step of cleaning an object to be treated, which contains a molybdenum-containing substance and has been subjected to chemical mechanical polishing, using the treatment liquid according to any one of [1] to [10].

[12] A method for manufacturing an electronic device, comprising:
the cleaning method for an object to be treated according to [11].

According to the present invention, it is possible to provide a treatment liquid which is excellent in anticorrosion properties for molybdenum and excellent in defect removability on an object to be treated, in a case of being applied to cleaning of the object to be treated, which has been subjected to a chemical mechanical polishing treatment and contains a molybdenum-containing substance.

In addition, according to the present invention, it is possible to provide a cleaning method for an object to be treated, using the above-described treatment liquid, and a method for manufacturing an electronic device.

### DESCRIPTION OF THE PREFERRED EMBODIMENTS

Hereinafter, the present invention will be described in detail.

The description of the configuration requirements described below is made on the basis of representative embodiments of the present invention, but it should not be construed that the present invention is limited to those embodiments.

In the present specification, numerical ranges represented by “to” include numerical values before and after “to” as lower limit values and upper limit values.

In the present specification, “total mass of components in the treatment liquid excluding a solvent” means the total mass of all components contained in the treatment liquid, other than a solvent such as water and an organic solvent.

In the present specification, in a case where there are two or more components corresponding to a certain component, “content” of such a component means the total content of the two or more components.

Unless otherwise specified, compounds described in the present specification may include structural isomers, optical isomers, and isotopes. In addition, one kind of structural isomer, optical isomer, and isotope may be included, or two or more kinds thereof may be included.

In the present specification, in a case of a plurality of substituents, linking groups, and the like (hereinafter, referred to as a substituent and the like) represented by specific reference numeral, or in a case of simultaneously defining a plurality of the substituent and the like, it means that each of the substituent and the like may be the same as or different with each other. The same applies to the definition of the number of substituents and the like.

A bonding direction of divalent groups cited in the present specification is not limited unless otherwise specified. For example, in a case where Y in a compound represented by Formula “X-Y-Z” is —COO—, Y may be —CO—O— or —O—CO—. In addition, the above-described compound may be “X—CO—O—Z” or “X—O—CO—Z”.

In the present specification, “psi” means pound-force per square inch, in which 1 psi=6894.76 Pa.

In the present specification, “ppm” means “parts-per-million (10⁻⁶)”, “ppb” means “parts-per-billion (10⁻⁹)”, “ppt” means “parts-per-trillion (10⁻¹²)”.

In the present specification, 1 angstrom (Å) corresponds to 0.1 nm.

In the present specification, unless otherwise specified, a molecular weight of a compound having a molecular weight distribution is a weight-average molecular weight.

In the present specification, in a case where a polymer to be used is a commercially available product and there are catalog values (manufacturer's values) for a weight-average molecular weight (Mw), a number-average molecular weight (Mn), and a polydispersity (also referred to as molecular weight distribution) (Mw/Mn) of the polymer, the catalog values are adopted.

For example, “PSSA-4” used in Examples described later is a product of FUJIFILM Wako Pure Chemical Corporation, and a weight-average molecular weight of 75,000, which is a catalog value, is used as a weight-average molecular weight of this polymer.

In a case where there is no catalog value or in a case where the weight-average molecular weight (Mw), the number-average molecular weight (Mn), and the polydispersity (Mw/Mn) of the polymer are determined by measurement, the weight-average molecular weight (Mw), the number-average molecular weight (Mn), and the polydispersity (Mw/Mn) are defined as values by gel permeation chromatography (GPC) measurement using a GPC device (ProminenceUFLC manufactured by Shimadzu Corporation) in terms of polystyrene (eluent: solution of phosphoric acid buffer solution (pH=7) and acetonitrile at a volume ratio of 9:1; flow volume (sample injection amount): 50 μL; columns: TSK guard column α+TSK gel α-6000+TSK gel α-3000 manufactured by Tosoh Corporation; column temperature: 40° C.; flow rate: 1.0 mL/min; detector: differential refractive index detector (refractive index detector)). The above description of “TSK guard column α+TSK gel α-6000+TSK gel α-3000” indicates that the three types of columns are used in combination.

In the present specification, unless otherwise specified, a molecular weight of a compound having a molecular weight distribution is a weight-average molecular weight.

The treatment liquid according to the embodiment of the present invention (hereinafter, also simply referred to as “present treatment liquid”) is a treatment liquid used for cleaning an object to be treated, which contains a molybdenum-containing substance and has been subjected to chemical mechanical polishing, the treatment liquid containing a polymer having a sulfonic acid group or a salt thereof, and water.

The mechanism by which the treatment liquid according to the embodiment of the present invention can solve the above-described problems is not necessarily clear, but the present inventors assume as follows.

The mechanism by which the effect is obtained is not limited by the following supposition. In other words, even in a case where an effect is obtained by a mechanism other than the following, it is included in the scope of the present invention.

In a case where an object to be treated, which contains a molybdenum-containing substance, is subjected to a CMP treatment, residues of a polished molybdenum are present on the object to be treated. In a case where the object to be treated in such a state is brought into contact with the present treatment liquid, the sulfonic acid group or a salt thereof in the polymer having a sulfonic acid group or a salt thereof (hereinafter, also simply referred to as “polymer (A)”) is adsorbed to a molybdenum region and the molybdenum residues on the object to be treated. As a result, since a zeta potential on the above-described molybdenum region and a zeta potential on the above-described molybdenum residues are close to each other and thus repel each other, it is considered that the residues are easily removed, and the defect removability is improved.

In addition, in this case, it is presumed that the anticorrosion properties are also improved since the polymer (A) is adsorbed in the molybdenum region on the object to be treated.

Hereinafter, each component contained in the present treatment liquid will be described in detail. In addition, the fact that at least one of the anticorrosion properties for molybdenum or the defect removability is more excellent in the present treatment liquid is also referred to as “effect of the present invention is more excellent”.

### [Polymer Having Sulfonic Acid Group or Salt Thereof]

The present treatment liquid contains a polymer having a sulfonic acid group or a salt thereof (hereinafter, also simply referred to as “polymer (A)”). The polymer (A) is a compound having a repeating unit, and thus is different from a sulfonic acid-based surfactant (dodecylbenzenesulfonic acid or the like), an organic acid (an organic acid having a hydroxy group and a carboxy group), and an amino acid described in detail later. A weight-average molecular weight of the polymer (A) is not particularly limited, but is preferably 500 or more, more preferably 1,500 or more, still more preferably 2,000 or more, particularly preferably 4,000 or more, and most preferably 5,000 or more. The upper limit thereof is not particularly limited, but is preferably 1,000,000 or less, more preferably 100,000 or less, and still more preferably 50,000 or less.

The polymer (A) is not particularly limited as long as it has a plurality of a sulfonic acid group or a salt thereof (hereinafter, also simply referred to as “specific sulfonic acid group”), and a known compound can be used, but a water-soluble compound is preferable. In the present specification, the “water-soluble compound” refers to a compound in which a mass dissolved in 100 g of neutral water at 20° C. is 0.1 g or more.

Examples of the polymer (A) include a polymer compound obtained by sulfonating a polymer compound as a base, and a polymer compound obtained by polymerizing a monomer having a sulfonic acid group or a salt thereof. At least one sulfonic acid group in the polymer (A) may be in the form of a salt.

Examples of the salt of the sulfonic acid group include an ammonium salt, a potassium salt, a sodium salt, and a lithium salt. However, it is preferable that a raw material (commercially available product, reagent, or the like) for supplying the polymer (A) does not contain a metal (sodium and the like).

More specific examples of the polymer (A) include sulfonic acid group-containing polystyrenes (polystyrene sulfonic acid and the like), polyvinylsulfonic acid, polyallylsulfonic acid, sulfonic acid group-containing polyacrylamide, sulfonic acid group-containing polyvinyl alcohol (sulfonic acid-modified polyvinyl alcohol), sulfonic acid group-containing polyvinyl acetate (sulfonic acid-modified polyvinyl acetate), sulfonic acid group-containing polyester, a copolymer of a (meth)acrylic group-containing monomer and a sulfonic acid group-containing monomer, aromatic sulfonic acid-formaldehyde condensates (naphthalene sulfonic acid-formaldehyde condensate and the like), derivatives thereof, and ammonium salts, potassium salts, sodium salts, and lithium salts thereof.

### <Repeating Unit A1>

It is preferable that the polymer (A) contains a repeating unit having a sulfonic acid group or a salt thereof (hereinafter, also simply referred to as “repeating unit A1”).

Examples of the repeating unit A1 include a repeating unit derived from a compound having the specific sulfonic acid group and an ethylenically unsaturated group. The ethylenically unsaturated group is a functional group having an ethylenically unsaturated bond. Examples of the ethylenically unsaturated group include an aromatic vinyl group, an acryloyloxy group (CH₂═CH—COO—), a methacryloyloxy group (CH₂═CCH₃—COO—), an acrylamide group (CH₂═CH—CONH—), a methacrylamide group (CH₂═CCH₃—CONH—), a maleimide group, a vinyl group, and a vinyl ether group.

As the aromatic vinyl group, a styryl group is preferable.

As the compound having the specific sulfonic acid group and an ethylenically unsaturated group, a compound represented by Formula (A1) is preferable.

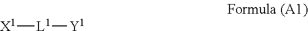

In Formula (A1), X¹ represents a sulfonic acid group or a salt thereof,
L¹ represents a single bond or a divalent linking group, and
Y¹ represents an ethylenically unsaturated group.

Specific aspects of the sulfonic acid group or a salt thereof, represented by X¹, are as described above. In addition, specific aspects and preferred aspects of the ethylenically unsaturated group represented by Y¹ are as described above.

Examples of the divalent linking group represented by L¹ include an ether bond (—O—), a carbonyl group (—CO—), an ester bond (—COO—), a thioether bond (—S—), —SO₂—, —NT-, a divalent hydrocarbon group (for example, an alkylene group, an alkenylene group, an alkynylene group, and an arylene group), and a group formed by combining two or more of these groups. T represents a hydrogen atom or a substituent.

The number of carbon atoms in the above-described divalent hydrocarbon group is preferably 1 to 20, more preferably 1 to 10, and still more preferably 1 to 6. In addition, the alkylene group and alkenylene group described above may be linear, branched, or cyclic.

The divalent linking group represented by L¹ may further have a substituent. Examples of the above-described substituent include an alkyl group, an aryl group, a heteroaryl group, a hydroxy group, a carboxy group, an amino group, and a halogen atom. Among the groups exemplified above, the number of carbon atoms in the alkyl group, the aryl group, and the heteroaryl group is preferably 1 to 20, more preferably 1 to 10, and still more preferably 1 to 6.

More specific examples of the compound having the specific sulfonic acid group and an ethylenically unsaturated group include p-styrene sulfonic acid and 2-acrylamido-2-methyl-1-propanesulfonic acid.

In the polymer (A), a content of the repeating unit A1 is preferably 5% by mole or more, more preferably 25% by mole or more, still more preferably 50% by mole or more, and particularly preferably 75% by mole or more with respect to all repeating units of the polymer (A). The upper limit of the above-described content is, for example, 100% by mole or less.

The polymer (A) may contain two or more kinds of the repeating units A1; and in this case, the total content thereof is preferably within the above-described numerical value range.

### <Repeating Unit A2>

From the viewpoint that the effect of the present invention is more excellent, the polymer (A) preferably has a carboxy group or a salt thereof (hereinafter, also simply referred to as “specific carboxy group”), and preferably contains a repeating unit having a carboxy group or a salt thereof (hereinafter, also simply referred to as “repeating unit A2”). The repeating unit A2 refers to a repeating unit different from the above-described repeating unit A1, and for example, a repeating unit having a sulfonic acid group and a carboxy group corresponds to the repeating unit A1. At least one carboxy group may be in the form of a salt.

Examples of the salt of the carboxy group include an ammonium salt, a potassium salt, a sodium salt, and a lithium salt.

Examples of the repeating unit A2 include a repeating unit derived from a compound having the specific carboxy group and an ethylenically unsaturated group. Specific examples of the ethylenically unsaturated group are as described above.

As the compound having the specific carboxy group and an ethylenically unsaturated group, a compound represented by Formula (A2) is preferable.

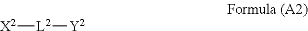

In Formula (A2), X² represents a carboxy group or a salt thereof,
L² represents a single bond or a divalent linking group, and
Y² represents an ethylenically unsaturated group.

Specific aspects of the carboxy group or a salt thereof, represented by X², are as described above. In addition, specific aspects and preferred aspects of the ethylenically unsaturated group represented by Y² are as described above.

Examples of the divalent linking group represented by L² include an ether bond (—O—), a carbonyl group (—CO—), an ester bond (—COO—), a thioether bond (—S—), —SO₂—, —NT-, a divalent hydrocarbon group (for example, an alkylene group, an alkenylene group, an alkynylene group, and an arylene group), and a group formed by combining two or more of these groups. T represents a hydrogen atom or a substituent.

The number of carbon atoms in the above-described divalent hydrocarbon group is preferably 1 to 20, more preferably 1 to 10, and still more preferably 1 to 6. In addition, the alkylene group and alkenylene group described above may be linear, branched, or cyclic.

The divalent linking group represented by L² may further have a substituent. Examples of the above-described substituent include an alkyl group, an aryl group, a heteroaryl group, a hydroxy group, a carboxy group, an amino group, and a halogen atom. Among the groups exemplified above, the number of carbon atoms in the alkyl group, the aryl group, and the heteroaryl group is preferably 1 to 20, more preferably 1 to 10, and still more preferably 1 to 6.

More specific examples of the compound having the specific carboxy group and an ethylenically unsaturated group include acrylic acid, maleic acid, itaconic acid, vinyl acetic acid, allyl acetic acid, and fumaric acid.

In the polymer (A), a content of the repeating unit A2 is preferably 75% by mole or less, more preferably 50% by mole or less, and still more preferably 25% by mole or less with respect to all repeating units of the polymer (A). The lower limit of the above-described content is not particularly limited, but is preferably 1% by mole or more.

In addition, a molar ratio C2/C1 of the content C2 of the repeating unit (repeating unit A2) having a carboxy group or a salt thereof to the content C1 of the repeating unit (repeating unit A1) having a sulfonic acid group or a salt thereof is preferably 95/5 to 1/99, more preferably 90/10 to 5/95, and still more preferably 85/15 to 15/85.

The polymer (A) may contain two or more kinds of the repeating units A2; and in this case, the total content thereof is preferably within the above-described numerical value range.

The polymer (A) may contain a repeating unit different from both the repeating unit A1 and the repeating unit A2.

Other repeating units are not particularly limited, and examples thereof include repeating units derived from compounds selected from the group consisting of an unsaturated alcohol compound, an aromatic vinyl compound, an alkyl (meth)acrylate compound which may have a hydroxy group, an aliphatic conjugated diene compound, a vinyl cyanide compound, and an amide compound having a polymerizable double bond.

Examples of the above-described aromatic vinyl compound include styrene, α-methylstyrene, vinyltoluene, and p-methylstyrene.

From the viewpoint that the effect of the present invention is more excellent, the polymer (A) is preferably a homopolymer consisting of the repeating unit A1; more preferably a homopolymer consisting of a repeating unit derived from an aromatic vinyl compound having the specific sulfonic acid group or a homopolymer consisting of a repeating unit derived from an acrylamide-based monomer having the specific sulfonic acid group; and still more preferably a homopolymer consisting of a repeating unit derived from styrene sulfonic acid, a homopolymer consisting of a repeating unit derived from a vinyl sulfonic acid, or a homopolymer consisting of a repeating unit derived from a 2-acrylamido-2-methyl-1-propanesulfonic acid.

In addition, from the viewpoint that the effect of the present invention is more excellent, it is also preferable that the polymer (A) is a copolymer consisting of the repeating unit A1 and the repeating unit A2. In the above-described copolymer, it is preferable that a ratio of the repeating unit A1 and the repeating unit A2 is in the above-described suitable range of the molar ratio C2/C1.

The above-described copolymer is preferably a copolymer consisting of a repeating unit derived from styrene sulfonic acid or a repeating unit derived from 2-acrylamido-2-methyl-1-propanesulfonic acid, and a repeating unit derived from acrylic acid or a repeating unit derived from maleic acid.

A content of the polymer (A) is preferably 0.0001% by mass or more, and more preferably 0.001% by mass or more with respect to the total mass of the treatment liquid. The upper limit of the above-described content is preferably 10.0% by mass or less, more preferably 1.0% by mass or less, and still more preferably 0.10% by mass or less.

The polymer (A) may be used alone or in combination of two or more kinds thereof. In a case where two or more kinds of the polymers (A) are used, it is also preferable that the total content thereof is within the above-described preferred range.

### [Organic Acid Having Hydroxy Group and Carboxy Group]

From the viewpoint that the effect of the present invention is more excellent, the present treatment liquid preferably contains an organic acid having a hydroxy group and a carboxy group (hereinafter, also simply referred to as “organic acid (B)”). In a case where the present treatment liquid contains the organic acid (B), the defect removability is more excellent.

The organic acid (B) is a compound different from the polymer (A).

The organic acid (B) is preferably α-hydroxycarboxylic acid (carboxylic acid having a hydroxy group at a carbon atom to which a carboxy group is bonded). In addition, the organic acid (B) may be any of an aliphatic hydroxycarboxylic acid or an aromatic hydroxycarboxylic acid, but is preferably an aliphatic hydroxycarboxylic acid, and more preferably an aliphatic hydroxycarboxylic acid having 1 to 15 carbon atoms.

Examples of the aliphatic hydroxycarboxylic acid include gluconic acid, heptonic acid, glycolic acid, glyceric acid, citric acid, malic acid, tartaric acid, lactic acid, and succinic acid.

Among these, the aliphatic hydroxycarboxylic acid preferably includes at least one selected from the group consisting of citric acid, tartaric acid, malic acid, and lactic acid.

Examples of the aromatic carboxylic acid include phenyllactic acid, hydroxyphenyllactic acid, and phenylsuccinic acid.

As the organic acid (B), a compound represented by Formula (B4) is preferable.

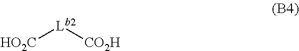

In Formula (B4), L^{b2} represents a divalent hydrocarbon group having a hydroxy group.

Examples of the above-described divalent hydrocarbon group include an alkylene group, an alkenylene group, an alkynylene group, an arylene group, and a group obtained by combining these groups.

The divalent hydrocarbon group may be linear, branched, or cyclic.

The divalent hydrocarbon group may have a substituent in addition to the hydroxy group. Examples of the above-described substituent include a carboxy group, an amino group, and a halogen atom.

Among these, an alkylene group is preferable as the divalent hydrocarbon group.

The number of carbon atoms in the divalent hydrocarbon group is preferably 1 to 15, more preferably 1 to 10, and still more preferably 1 to 5.

A content of the organic acid (B) is preferably 0.0001% to 10.0% by mass, more preferably 0.0001% to 1.0% by mass, and still more preferably 0.001% to 0.1% by mass with respect to the total mass of the present treatment liquid.

The organic acid (B) may be used alone or in combination of two or more kinds thereof. In a case where two or more kinds of the organic acids (B) are used, it is also preferable that the total content thereof is within the above-described preferred range.

In a case where the present treatment liquid contains the organic acid (B), a mass ratio of the content of the organic acid (B) to the content of the polymer (A) is preferably 0.001 to 500, more preferably 0.010 to 200, still more preferably 0.050 to 50, and particularly preferably 0.10 to 5.0.

### [Amino Acid]

From the viewpoint that the effect of the present invention is more excellent, the present treatment liquid preferably contains an amino acid.

The amino acid refers to an organic compound having an amino group and a carboxy group in the molecule, and refers to a compound different from the polymer (A) and the organic acid (B).

Examples of the amino acid include an α-amino acid having an amino group on a carbon atom (α-carbon) to which a carboxy group is bonded, a β-amino acid having an amino group on a carbon atom (β-carbon) to which α-carbon is bonded, and a γ-amino acid having an amino group on a carbon atom (γ-carbon) to which β-carbon is bonded; and among these, an α-amino acid is preferable.

As the amino acid, a compound represented by Formula (B1) or Formula (B2) is preferable.

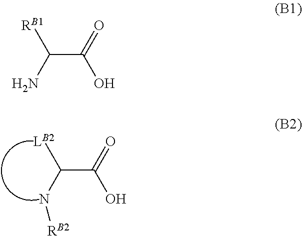

In Formula (B1), R^{B1} represents a hydrogen atom or an alkyl group which may have a substituent. The number of carbon atoms in an alkyl group moiety of the alkyl group which may have a substituent, represented by R^{B1}, is preferably 1 to 6. A methylene group constituting the above-described alkyl group moiety may be substituted with —CO—, —O—, or —S—. The above-described alkyl group moiety may be linear or branched, and may have a cyclic structure. Examples of the substituent of the alkyl group which may have a substituent, represented by R^{B1}, include a phenyl group, a hydroxy group, a hydroxyphenyl group, a thiol group, a primary amino group, a secondary amino group, an imidazolyl group, an indolyl group, and a guanidino group; and a primary amino group, a secondary amino group, an imidazolyl group, an indolyl group, or a guanidino group is preferable. The alkyl group which may have a substituent, represented by R^{B1}, may have a plurality of substituents.

Examples of the compound represented by Formula (B1) include alanine, arginine, asparagine, cysteine, glutamine, glycine, histidine, leucine, isoleucine, lysine, hydroxylysine, methionine, phenylalanine, serine, threonine, tryptophan, tyrosine, and valine.

In Formula (B2), L^{B2} represents a divalent linking group. L^{B2} preferably represents an alkylene group having 1 to 6 carbon atoms, which may have a substituent. Examples of the above-described substituent include the substituents which may be included in R^{B1} described above.

In Formula (B2), R^{B2} represents a hydrogen atom or an alkyl group which may have a substituent. Since a preferred aspect of the alkyl group which may have a substituent, represented by R^{B2}, is the same as the preferred aspect of the alkyl group which may have a substituent, represented by R^{B1}, a description thereof will not be repeated.

In the compound represented by Formula (B2), L^{B2} is bonded to a nitrogen atom.

Examples of the compound represented by Formula (B2) include piperidine-2-carboxylic acid, N-methylpiperidine-2-carboxylic acid, proline, N-methylproline, and hydroxyproline.

As the amino acid, arginine, asparagine, glutamine, histidine, lysine, hydroxylysine, or tryptophan is preferable; and from the viewpoint that the surface roughness can be further suppressed, arginine, histidine, or lysine is more preferable. That is, a basic amino acid is more preferable.

A content of the amino acid is preferably 0.00001% to 10.0% by mass, more preferably 0.0001% to 5.0% by mass, and still more preferably 0.001% to 1.0% by mass with respect to the total mass of the present treatment liquid.

The amino acid may be used alone or in combination of two or more kinds thereof. In a case where two or more kinds of the amino acids are used, it is also preferable that the total content thereof is within the above-described preferred range.

In a case where the present treatment liquid contains the amino acid, a mass ratio of the content of the amino acid to the content of the polymer (A) is preferably 0.001 to 500, more preferably 0.010 to 200, still more preferably 0.050 to 50, and particularly preferably 0.10 to 5.0.

In addition, in a case where the present treatment liquid contains the organic acid (B) and the amino acid, a mass ratio of the content of the organic acid (B) to the content of the amino acid is preferably 0.001 to 200 and more preferably 0.10 to 5.0.

### [Water]

The present treatment liquid contains water.

The type of water used in the present treatment liquid may be any type of water as long as it does not adversely affect the semiconductor substrate; and distilled water, deionized (DI) water, or pure water (ultrapure water) can be used. The pure water (ultrapure water) is preferable from the viewpoint that it contains almost no impurities and has less influence on a semiconductor substrate in a step of manufacturing the semiconductor substrate.

A content of water may be a remainder of components which can be contained in the treatment liquid.

The content of water is preferably 80% by mass or more, more preferably 85% by mass or more, and still more preferably 90% by mass or more with respect to the total mass of the treatment liquid. From the viewpoint that the effect of the present invention is more excellent, the upper limit thereof is preferably 99.999% by mass or less, more preferably 99.99% by mass or less, and still more preferably 99.97% by mass or less.

### [Other Components]

The treatment liquid may contain, in addition to the above-described compounds, at least one component selected from the group consisting of a preservative (antibacterial agent), a polymer which does not have a sulfonic acid group, a chelating agent, a quaternary ammonium compound, an oxidizing agent, a reducing agent, an organic solvent, a pH adjuster, a fluorinated compound (hydrofluoric acid and the like), a surfactant, a polyhydroxy compound having a molecular weight of 500 or more, and dissolved gas.

Hereinafter, other components will be described.

### <Preservative>

The treatment liquid may contain a preservative.

The preservative is a compound different from the components contained in the present treatment liquid described above.

Examples of the preservative include benzoic acid, sodium benzoate, salicylic acid, propionic acid, isopropyl paraoxybenzoate, isobutyl paraoxybenzoate, ethyl paraoxybenzoate, methyl paraoxybenzoate, butyl paraoxybenzoate, propyl paraoxybenzoate, sodium sulfite, sodium hyposulfite, potassium pyrosulfite, sorbic acid, potassium sorbate, sodium dehydroacetate, thujaplicin, Aralia cordata extract, Styrax japonicus extract; Artemisia capillaris extract, oolong tea extract, fish milt protein extract, enzymatically hydrolyzed Coix lacryma-jobi extract, tea catechins, apple polyphenols, pectin hydrolysate, chitosan, lysozyme, and ε-polylysine.

Among these, as the preservative, benzoic acid, sorbic acid, salicylic acid, or propionic acid is preferable.

A content of the preservative is preferably 0.0001% to 10.0% by mass, more preferably 0.0001% to 1.0% by mass, and still more preferably 0.0001% to 0.1% by mass with respect to the total mass of the treatment liquid.

### <Polymer Having No Sulfonic Acid Group or Salt Thereof>

The treatment liquid may contain a polymer which does not have a sulfonic acid group or a salt thereof.

The polymer which does not have a sulfonic acid group or a salt thereof is preferably a water-soluble polymer.

The “water-soluble polymer” means a compound having two or more structural units linked in a linear or mesh form through a covalent bond, in which a mass of the polymer dissolved in 100 g of water at 20° C. is 0.1 g or more.

Examples of the water-soluble polymer include polyacrylic acid, polymethacrylic acid, polymaleic acid, and salts thereof; copolymers of a monomer such as styrene, α-methylstyrene, and/or 4-methylstyrene and a monomer of an acid such as (meth)acrylic acid and/or maleic acid, and salts thereof; copolymers of (meth)acrylic acid and maleic acid, and salts thereof; vinyl-based synthetic polymers such as polyvinyl alcohol, polyoxyethylene, polyvinylpyrrolidone, polyvinylpyridine, polyacrylamide, polyvinylformamide, polyethyleneimine, polyvinyloxazoline, polyvinylimidazole, and polyallylamine; and modified products of natural polysaccharides such as hydroxyethyl cellulose, carboxymethyl cellulose, and processed starch.

Among these, as the water-soluble polymer, a polymer having an acid group (for example, a carboxy group or a phosphoric acid group) or a salt thereof, other than the sulfonic acid group or a salt thereof, is preferable; and a copolymer of polyacrylic acid, polymaleic acid, styrene and/or a monomer of an acid such as (meth)acrylic acid, a copolymer of (meth)acrylic acid and maleic acid, or salts thereof are more preferable.

A content of the polymer which does not have a sulfonic acid group or a salt thereof is preferably 0.0001% to 10% by mass, more preferably 0.001% to 1% by mass, and still more preferably 0.001% to 0.1% by mass with respect to the total mass of the treatment liquid.

### <Chelating Agent>

The present treatment liquid may contain a chelating agent. The chelating agent is a compound different from the components contained in the present treatment liquid described above.

The chelating agent is a compound having a functional group (coordinating group) which can function as a ligand.

As the coordinating group in the chelating agent, a carboxy group or a phosphonic acid group is preferable.

Examples of the chelating agent include an organic chelating agent and an inorganic chelating agent.

The organic chelating agent is a chelating agent containing an organic compound, and examples thereof include a carboxylic acid-based chelating agent having a carboxy group as a coordinating group and a phosphonic acid-based chelating agent having a phosphonic acid group as a coordinating group.

Examples of the inorganic chelating agent include a fused phosphoric acid and a salt thereof.

As the chelating agent, the organic chelating agent is preferable.

The chelating agent preferably has a low molecular weight. Specifically, the molecular weight of the chelating agent is preferably 600 or less, more preferably 450 or less, and still more preferably 300 or less. The lower limit thereof is preferably 50 or more and more preferably 100 or more.

The number of carbon atoms in the chelating agent is preferably 1 to 15 and more preferably 2 to 15.

### (Carboxylic Acid-Based Chelating Agent)

Examples of the carboxylic acid-based chelating agent include a polycarboxylic acid.

The polycarboxylic acid is a compound having two or more carboxy groups in the molecule and not having a hydroxy group and an amino group in the molecule.

Examples of the polycarboxylic acid include malonic acid, maleic acid, oxalic acid, glutaric acid, adipic acid, pimelic acid, and sebacic acid.

### (Phosphonic Acid-Based Chelating Agent)

Examples of the phosphonic acid-based chelating agent include 1-hydroxyethyldiene-1,1′-diphosphonic acid (etidronic acid; HEDP), ethylidenediphosphonic acid, 1-hydroxypropyridene-1,1′-diphosphonic acid, 1-hydroxybutylidene-1,1′-diphosphonic acid, ethylaminobis(methylenephosphonic acid), dodecylaminobis(methylenephosphonic acid), and nitrilotris(methylenephosphonic acid) (NTPO).

As the phosphonic acid-based chelating agent other than those described above, compounds described in paragraphs [0026] to [0036] of WO2018/020878A and compounds ((co)polymers) described in paragraphs [0031] to [0046] of WO2018/030006A can be used, the contents of which are incorporated herein by reference.

Among these, as the phosphonic acid-based chelating agent, HEDP or NTPO is preferable.

A content of the chelating agent is preferably 0.0001% to 10.0% by mass, more preferably 0.0001% to 1.0% by mass, and still more preferably 0.001% to 0.1% by mass with respect to the total mass of the present treatment liquid.

### <Quaternary Ammonium Compound>

The present treatment liquid may contain a quaternary ammonium compound.

The quaternary ammonium compound is a compound different from the above-described compounds which can be contained in the present treatment liquid.

The quaternary ammonium compound may be a quaternary ammonium cation (ammonia) having no hydrocarbon group, but is preferably a compound having a quaternary ammonium cation in which a nitrogen atom is substituted with four hydrocarbon groups (preferably, alkyl groups). In addition, the quaternary ammonium compound may be a compound having a quaternary ammonium cation in which a nitrogen atom in a pyridine ring is bonded to a substituent (a hydrocarbon group such as an alkyl group and an aryl group), for example, an alkyl pyridinium.

Examples of the quaternary ammonium compound include a quaternary ammonium hydroxide, a quaternary ammonium fluoride, a quaternary ammonium bromide, a quaternary ammonium iodide, a quaternary ammonium acetate, and a quaternary ammonium carbonate.

Examples of the quaternary ammonium compound include ethyltrimethylammonium hydroxide (ETMAH), tris(2-hydroxyethyl)methylammonium hydroxide (THEMAH), dimethylbis(2-hydroxyethyl)ammonium hydroxide, tetramethylammonium hydroxide (TMAH), trimethylethylammonium hydroxide (TMEAH), dimethyldiethylammonium hydroxide (DMDEAH), methyltriethylammonium hydroxide (MTEAH), tetraethylammonium hydroxide (TEAH), tetrapropylammonium hydroxide (TPAH), tetrabutylammonium hydroxide (TBAH), 2-hydroxyethyltrimethylammonium hydroxide (choline), bis(2-hydroxyethyl)dimethylammonium hydroxide, tri(2-hydroxyethyl)methylammonium hydroxide, tetra(2-hydroxyethyl)ammonium hydroxide, benzyltrimethylammonium hydroxide (BTMAH), and cetyltrimethylammonium hydroxide; and Tris, choline, or ETMAH is preferable.

A content of the quaternary ammonium compound is preferably 0.01% to 20.0% by mass, more preferably 0.05% to 15.0% by mass, and still more preferably 0.1% to 10.0% by mass with respect to the total mass of the treatment liquid.

### <Reducing Agent>

The present treatment liquid may contain a reducing agent.

The reducing agent is a compound having a reducing action and a function of reducing OH⁻ ions or dissolved oxygen contained in the treatment liquid, and is also referred to as an oxygen scavenger. The reducing agent functions as an anticorrosion agent which improves corrosion prevention performance of the treatment liquid.

The reducing agent used in the treatment liquid is not particularly limited, and examples thereof include an ascorbic acid compound, a catechol compound, a hydroxylamine compound, a hydrazide compound, and a reducing sulfur compound.

As specific examples of the ascorbic acid compound, the catechol compound, the hydroxylamine compound, the hydrazide compound, and the reducing sulfur compound, compounds described in paragraphs [0084] to [0093] of WO2021/131452A can be referred to, the contents of which are incorporated in the present specification.

### <Organic Solvent>

The present treatment liquid may contain an organic solvent. Examples of the organic solvent include known organic solvents, for example, an alcohol-based solvent, a glycol-based solvent, a glycol ether-based solvent, and a ketone-based solvent.

It is preferable that the organic solvent is mixed with water at an optional ratio.

As the organic solvent, for example, compounds exemplified in paragraphs [0135] to [0140] of WO2022/044893A can be used, the contents of which are incorporated herein by reference.

### <pH Adjuster>

The present treatment liquid may contain a pH adjuster to adjust and maintain the pH of the present treatment liquid.

The pH adjuster is a basic compound and an acidic compound, which are different from the components contained in the present treatment liquid described above. However, it is permissible to adjust the pH of the present treatment liquid by adjusting the adding amount of each of the components which can be contained in the present treatment liquid.

The basic compound is a compound which exhibits basicity (pH of more than 7.0) in an aqueous solution, and examples thereof include a basic inorganic compound.

Examples of the basic inorganic compound include amine compounds such as tris(hydroxymethyl)aminomethane, alkali metal hydroxides such as sodium hydroxide and potassium hydroxide, and alkaline earth metal hydroxides.

The acidic compound as the pH adjuster is a compound which exhibits acidity (pH of less than 7.0) in an aqueous solution, and examples thereof include an acidic inorganic compound.

Examples of the acidic inorganic compound include hydrochloric acid, nitric acid, nitrous acid, sulfurous acid, phosphoric acid, boric acid, carbonic acid, hypophosphorous acid, phosphorous acid, and hexafluorophosphoric acid.

As the acidic compound as the pH adjuster, a salt of the acidic compound may be used as long as it is an acid or an acid ion (anion) in an aqueous solution.

A content of the pH adjuster can be selected depending on the type and amount of other components and the target pH of the treatment liquid. For example, the content of the pH adjuster is preferably 0.0001% to 10% by mass, more preferably 0.001% to 8% by mass, and still more preferably 0.001% to 0.1% by mass with respect to the total mass of the treatment liquid.

### <Dissolved Gas>

The present treatment liquid may contain dissolved gas. By setting a concentration of the dissolved gas in the treatment liquid to an appropriate range, it is possible to improve the defect removability.

The concentration of the dissolved gas is preferably 0.01 to 10 mg/L with respect to the total volume of the present treatment liquid.

From the viewpoint that the residue removal effect is more excellent, the concentration of the dissolved gas is preferably 0.05 mg/L or more and more preferably 0.1 mg/L or more with respect to the total volume of the present treatment liquid. On the other hand, from the viewpoint of more excellent storage stability, the concentration of the dissolved gas is preferably 7 mg/L or less, more preferably 4 mg/L or less, and still more preferably 1.5 mg/L or less with respect to the total volume of the present treatment liquid.

The dissolved gas is not particularly limited, but clean air is preferable. In the present specification, the “clean air” represents air having a Class of 8 or less (Class 8 or less than Class 8) in ISO standard ISO 14644-1: 2015.

The concentration of the dissolved gas in the present treatment liquid can be evaluated as a total value of concentrations of oxygen gas (O₂ gas), nitrogen gas (N₂ gas), and carbon dioxide gas (CO₂ gas) by measuring the concentrations thereof. As a method of measuring the oxygen gas, the nitrogen gas, and the carbon dioxide gas, a treatment method described in paragraph [0020] of WO2020/194978A can be used, the content of which is incorporated in the present specification.

The concentration of the dissolved gas can be controlled by a known method, and for example, methods described in paragraphs [0019], [0052] to [0056], and [0060] to [0062] of WO2020/194978A can be referred to, the contents of which are incorporated in the present specification.

### <Abrasive Particles>

It is preferable that the treatment liquid does not substantially contain abrasive particles.

The abrasive particles mean particles which are contained in a polishing liquid used for performing a polishing treatment on a semiconductor substrate and have an average primary particle diameter of 5 nm or more.

Examples of the above-described abrasive particles include inorganic solids such as silica (including colloidal silica and fumed silica), alumina, zirconia, ceria, titania, germania, manganese oxide, and silicon carbide; and organic solids such as polystyrene, a polyacrylic resin, and polyvinyl chloride.

The expression “does not substantially contain the abrasive particles” means that the content of the abrasive particles is less than 0.1% by mass, preferably 0.01% by mass or less, and more preferably 0.001% by mass or less with respect to the total mass of the treatment liquid. The lower limit thereof is not particularly limited, and is 0% by mass.

The content of the abrasive particles can be measured using a commercially available measuring device in a light scattering type liquid particle measuring method using a laser as a light source.

In addition, an average primary particle diameter of particles such as abrasive particles is determined by measuring particle diameters (equivalent circle diameter) of 1,000 primary particles randomly selected from an image obtained using a transmission electron microscope TEM2010 (acceleration voltage: 200 kV) manufactured by JEOL Ltd., and calculating an arithmetic mean thereof. The equivalent circle diameter is a diameter of a virtual perfect circle assumed to have the same projected area as the projected area of particles observed.

Examples of a method for removing the abrasive particles from the treatment liquid include a purification treatment such as filtering.

### [Physical Properties of Treatment Liquid]

<pH>

The treatment liquid may be alkaline or acidic.

From the viewpoint that the effect of the present invention is more excellent, the pH of the treatment liquid is preferably 2.0 to 12.0, more preferably 3.0 to 9.0, and still more preferably 4.0 to 7.0.

The pH of the treatment liquid can be measured by a method based on JIS Z 8802-1984 using a known pH meter. A measurement temperature of the pH is 25° C.

### <Metal Content>

A content (measured as ion concentration) of all metals (for example, metal elements of Fe, Co, Na, Cu, Mg, Mn, Li, Al, Cr, Ni, Zn, Sn, and Ag) contained as impurities in the treatment liquid is preferably 5 mass ppm or less, and more preferably 1 mass ppm or less. Among these, a content of sodium atoms in the treatment liquid is preferably 1 ppm by mass or less with respect to the total mass of the treatment liquid.

It is assumed that, in manufacturing of a cutting-edge semiconductor element, the present composition having even higher purity is required, and thus the metal content is more preferably a value lower than 1 mass ppm, that is, lower than a value of mass ppb order, particularly preferably 100 mass ppb or less, and most preferably less than 10 mass ppb. The lower limit thereof is preferably 0.

Examples of a method for reducing the metal content include performing a purifying treatment such as distillation and filtration using an ion exchange resin or a filter at a stage of raw materials used in the production of the treatment liquid or a stage after the production of the treatment liquid.

Other examples of the method for reducing the metal content include using a container with less elution of impurities, which will be described later, as a container that accommodates the raw material or the produced treatment liquid. In addition, other examples thereof include lining an interior wall of the pipe with a fluororesin to prevent the elution of metal components from a pipe or the like during the production of the treatment liquid.

### <Insoluble Particles>

It is preferable that the treatment liquid does not substantially contain insoluble particles.

The “insoluble particles” are particles of an inorganic solid, an organic solid, and the like, and correspond to particles which are present as particles without being finally dissolved in the treatment liquid.

The expression “does not substantially contain insoluble particles” means that the number of particles having a particle diameter of 40 nm or more, contained in 1 mL of a composition for measurement, is 40,000 or less in a case where the treatment liquid is diluted 10,000 times with the solvent contained in the treatment liquid to obtain the composition for measurement. The number of the particles contained in the composition for measurement can be measured in a liquid phase using a commercially available particle counter.

As a commercially available particle counter device, a device manufactured by RION Co., Ltd. or a device manufactured by PMS Co., Ltd. can be used. Representative examples of the device of the former include KS-19F, and representative examples of the device of the latter include UltraChem 40. In order to measure larger coarse particles, a device such as KS-42 series or LiQuilaz II S series can be used.

Examples of the insoluble particles include inorganic solids such as silica (including colloidal silica and fumed silica), alumina, zirconia, ceria, titania, germania, manganese oxide, and silicon carbide; and organic solids such as polystyrene, a polyacrylic resin, and polyvinyl chloride.

Examples of a method for removing the abrasive particles from the treatment liquid include a purification treatment such as filtering.

### <Coarse Particles>

The treatment liquid may contain coarse particles, but it is preferable that a content thereof is preferably low.

The coarse particles mean particles having a diameter (particle size) of 1 μm or more, in a case where a shape of the particles is regarded as a sphere.

The coarse particles contained in the treatment liquid correspond to, for example, particles such as rubbish, dust, organic solid, and inorganic solid, which are contained as impurities in raw materials, and particles such as rubbish, dust, organic solid, and inorganic solid, which are brought in as contaminants during the preparation of the treatment liquid, in which those particles are finally present as particles without being dissolved in the treatment liquid.

The content of the coarse particles in the treatment liquid, in terms of content of particles having a particle size of 1 μm or more, is preferably 100 or less and more preferably 50 or less per 1 mL of the treatment liquid. The lower limit thereof is preferably 0 or more, and more preferably 0.01 or more per milliliter of the treatment liquid.

The content of the coarse particles present in the treatment liquid can be measured in a liquid phase by using a commercially available measuring device in a light scattering type liquid particle measuring method using a laser as a light source.

Examples of a method for removing the coarse particles include a purification treatment such as filtering, which will be described later.

### [Production Method of Treatment Liquid]

The treatment liquid can be produced by a known method. Hereinafter, a production method of the treatment liquid will be described in detail.

### [Liquid Preparation Step]

The treatment liquid can be produced, for example, by mixing the above-described components.

Examples of the method for preparing the treatment liquid include a method in which the polymer having a sulfonic acid group or a salt thereof and the optional component as necessary are sequentially charged into a container containing purified pure water, the mixture is stirred and mixed, and a pH adjuster is added as necessary to adjust the pH of the mixed solution, thereby preparing the treatment liquid. In addition, in a case where the respective components are charged into the container, the respective components may be charged at once, or may be charged in a divided manner a plurality of times.

As a stirring device and a stirring method used for preparing the treatment liquid, a known device may be used as a stirrer or a disperser. Examples of a stirrer include an industrial mixer, a portable stirrer, a mechanical stirrer, and a magnetic stirrer. Examples of the disperser include an industrial disperser, a homogenizer, an ultrasonic disperser, and a beads mill.

The mixing of the respective components in the step of preparing the treatment liquid, a refining treatment described later, and storage of the produced treatment liquid are preferably performed at 40° C. or lower, and more preferably performed at 30° C. or lower. The lower limit thereof is preferably 5° C. or higher and more preferably 10° C. or higher. By performing the preparation of the treatment liquid, the treatment, and/or the storage of the treatment liquid in the above-described temperature ranges, the performance can be stably maintained for a long period of time.

### <Purification>

It is preferable to subject any one or more of the raw materials for preparing the treatment liquid to a purification treatment in advance. Examples of the purification treatment include known methods such as distillation, ion exchange, and filtration (filtering).

Regarding a degree of purification, it is preferable to carry out the purification treatment until the purity of the raw material is 99% by mass or more, and it is more preferable to carry out the purification treatment until the purity of the raw material is 99.9% by mass or more. The upper limit thereof is preferably 99.9999% by mass or less.

Examples of a method of the purification treatment include a method of passing the raw material through an ion exchange resin, a reverse osmosis membrane (RO membrane), or the like, reprecipitation, distillation of a raw material, and filtering.

The purification treatment may be performed by combining a plurality of the above-described purification methods. For example, the raw materials are subjected to primary purification by passing through an RO membrane, and then subjected to secondary purification by passing through a purification device consisting of a cation-exchange resin, an anion-exchange resin, or a mixed-bed type ion exchange resin.

In addition, the purification treatment may be performed a plurality of times.

The filter which is used for filtering is not particularly limited as long as it has been used in application for filtering and the like in the related art. Examples thereof include filters formed of fluororesins such as polytetrafluoroethylene (PTFE) and tetrafluoroethylene perfluoroalkyl vinyl ether copolymer (PFA), polyamide-based resins such as nylon, polyarylsulfone (PAS), polyolefin resins (including those with a high density and a ultra-high molecular weight) such as polyethylene and polypropylene (PP), or the like. Among these materials, a material selected from the group consisting of polyethylene, polypropylene (including a high-density polypropylene), a fluororesin (including PTFE and PFA), and a polyamide-based resin (including nylon) is preferable; and a filter of the fluororesin is more preferable. By carrying out filtering of the raw materials using a filter formed of these materials, high-polarity foreign matters which are likely to cause defects can be more effectively removed.

### <Container>

The treatment liquid (including an aspect of a diluted treatment liquid described later) can be added in any container to be stored and transported as long as problems such as corrosiveness do not arise.

In application for a semiconductor, the container is preferably a container which has a high degree of cleanliness inside the container and in which the elution of impurities from an interior wall of an accommodating portion of the container into the each liquid is suppressed. Examples of such a container include various containers commercially available as a container for a semiconductor treatment liquid, such as “CLEAN BOTTLE” series manufactured by AICELLO MILIM CHEMICAL Co., Ltd. and “PURE BOTTLE” manufactured by Kodama Plastics Co., Ltd., but the container is not limited thereto.

In addition, as the container, containers exemplified in paragraphs [0121] to [0124] of WO2022/004217A can also be used, the contents of which are incorporated herein by reference.

The inside of these containers is preferably cleaned before filling the treatment liquid. With regard to a liquid used for the cleaning, the amount of metal impurities in the liquid is preferably reduced. The treatment liquid may be bottled in a container such as a gallon bottle and a coated bottle after the production, and then may be transported and stored.

In order to prevent changes in the components of the treatment liquid during the storage, the inside of the container may be purged with an inert gas (such as nitrogen and argon) having a purity of 99.99995% by volume or more. In particular, a gas with a low moisture content is preferable. In addition, during the transportation and the storage, the temperature may be normal temperature or may be controlled in a range of −20° C. to 20° C. to prevent deterioration.

### <Clean Room>

It is preferable that handlings including production of the treatment liquid, opening and cleaning of the container, and filling of the treatment liquid, treatment analysis, and measurements are all performed in a clean room. It is preferable that the clean room meets the 14644-1 clean room standard. It is preferable that the clean room satisfies any one of International Organization for Standardization (ISO) Class 1, ISO Class 2, ISO Class 3, or ISO Class 4, it is more preferable that the clean room satisfies ISO Class 1 or ISO Class 2, and it is still more preferable that the clean room satisfies ISO Class 1.

### [Dilution Step]

The treatment liquid may be used for treating an object to be treated, as a diluted treatment liquid after undergoing a dilution step of diluting the concentrated solution using a diluent such as water.

The concentrated solution and the diluted treatment liquid are also aspects of the treatment liquid according to the embodiment of the present invention as long as they satisfy the requirements of the present invention.

It is preferable to subject the diluent which is used in the dilution step to a purification treatment in advance. In addition, it is more preferable that the diluted treatment liquid obtained in the dilution step is subjected to a purification treatment.

Examples of the purification treatment include the ion component reducing treatment using the ion exchange resin, the RO membrane, or the like, and the foreign matter removal using filtering, which are described as the purification treatment for the treatment liquid above, and it is preferable to carry out any one of these treatments.

A dilution rate of the treatment liquid in the dilution step may be appropriately adjusted depending on the type and content of each component and the object to be treated, but the ratio (dilution ratio) of the diluted treatment liquid to the treatment liquid before the dilution is preferably 10 to 10,000 times, more preferably 20 to 3,000 times, and still more preferably 50 to 1,000 times in terms of mass ratio or volume ratio (volume ratio at 23° C.).

In addition, from the viewpoint of more excellent defect removability, the treatment liquid is preferably diluted with water (preferably, ultrapure water).

A change in pH before and after the dilution (a difference between the pH of the treatment liquid before the dilution and the pH of the diluted treatment liquid) is preferably 2.0 or less, more preferably 1.8 or less, and still more preferably 1.5 or less.

It is preferable that the pH of the treatment liquid before the dilution and the pH of the diluted treatment liquid are each in the above-described suitable aspect.

A specific method for the dilution step of diluting the treatment liquid may be performed according to the step of preparing the treatment liquid described above. A stirring device and a stirring method used in the dilution step may also be performed using the known stirring device described in the step of preparing the treatment liquid above.

### [Use Application]

The treatment liquid is used in a cleaning step of an object to be treated which has been subjected to chemical mechanical polishing (CMP) treatment and contains a molybdenum-containing substance (hereinafter, also simply referred to as “object to be treated”). The object to be treated is often a semiconductor substrate.

The treatment liquid may be used in other steps after the CMP treatment and before the cleaning step, and for example, may be used in a step of cleaning the object to be treated after the CMP treatment through a pad cleaning treatment step. In addition, the treatment liquid may be used for cleaning a semiconductor substrate in any step in the manufacturing process of the semiconductor substrate.

As described above, in a case where the treatment liquid is used, the treatment liquid may be used as a diluted treatment liquid obtained by diluting the treatment liquid.

Hereinafter, the object to be treated of the treatment liquid according to the embodiment of the present invention will be described in detail.

### [Object to be Treated]

The object to be treated is an object to be treated, which has been subjected to the CMP treatment and contains a molybdenum (Mo)-containing substance, and is often a Mo-containing substrate (semiconductor substrate) containing Mo. Mo may be located on any of a front surface, a back surface, side surfaces, the inside of the groove, or the like of the semiconductor substrate. In addition, the object to be treated includes not only a case where Mo is directly present on the surface of the semiconductor substrate but also a case where Mo is present on the semiconductor substrate through another layer.

As the Mo-containing substrate, an Mo-containing substrate having a region containing Mo and Mo-based residues containing Mo is preferable, and an Mo-containing semiconductor substrate having a region containing Mo and Mo-based residues containing Mo is more preferable.

Examples of the presence form of Mo in the object to be treated include a metal, an oxide, and a nitride; and a metal is preferable. That is, the region containing Mo is preferably a region containing Mo in a metal state.

In a case where the object to be treated contains Mo in a metal state, the contained Mo may be in a state of an alloy containing Mo. Examples of elements other than Mo, which are contained in the alloy containing Mo, include copper (Cu), cobalt (Co), tungsten (W), ruthenium (Ru), aluminum (Al), titanium (Ti), and tantalum (Ta); and W is preferable.

The object to be treated may be a semiconductor substrate having at least one of a metal wire film, an insulating film, or a barrier metal.

In addition, Mo may be contained as a metal wire film or as a barrier metal.

Examples of a wafer constituting the semiconductor substrate include a wafer consisting of a silicon-based material, such as a silicon (Si) wafer, a silicon carbide (SiC) wafer, and a silicon-including resin-based wafer (glass epoxy wafer), a gallium phosphorus (GaP) wafer, a gallium arsenic (GaAs) wafer, and an indium phosphorus (InP) wafer.

Examples of the silicon wafer include an n-type silicon wafer in which a silicon wafer is doped with a pentavalent atom (for example, phosphorus (P), arsenic (As), antimony (Sb), or the like) and a p-type silicon wafer in which a silicon wafer is doped with a trivalent atom (for example, boron (B), gallium (Ga), or the like). Examples of the silicon of the silicon wafer include amorphous silicon, single crystal silicon, polycrystalline silicon, and polysilicon.

Among these, a wafer consisting of a silicon-based material, such as a silicon wafer, a silicon carbide wafer, and a resin-based wafer (a glass epoxy wafer) including silicon, is preferable.

Examples of the insulating film include a silicon oxide film (for example, a silicon dioxide (SiO₂) film, a tetraethyl orthosilicate (Si(OC₂H₅)₄) film (a TEOS film), a silicon nitride film (for example, silicon nitride (Si₃N₄), and silicon nitride carbide (SiNC)), and a low-dielectric-constant (Low-k) film (for example, a carbon-doped silicon oxide (SiOC) film, a black diamond (BD) film, and a silicon carbide (SiC) film); and a low-dielectric-constant (Low-k) film is preferable.

In addition to Mo, examples of the barrier metal include tantalum (Ta), tantalum nitride (TaN), titanium nitride (TiN), tungsten (W), tungsten alloy (tungsten-titanium (WTi) alloy, tungsten-cobalt (WCo) alloy, and the like), cobalt (Co), cobalt alloy, ruthenium (Ru), and ruthenium alloy.

A method of forming the molybdenum-containing film and the insulating film on the wafer constituting the semiconductor substrate is not particularly limited as long as it is a method generally performed in this field.

Examples of the method of forming the molybdenum-containing film include a method of forming a circuit on the wafer by a known method such as a resist, and then forming the metal layer by a method such as plating, a physical vapor deposition (PVD) method, and a CVD method. The object to be treated may have a layer for forming the molybdenum-containing film on the insulating film.

Examples of the method of forming the insulating film include a method in which the wafer constituting the semiconductor substrate is subjected to a heat treatment in the presence of oxygen gas to form a silicon oxide film, and then a gas of silane and ammonia is introduced thereto to form a silicon nitride film by a chemical vapor deposition (CVD) method.

### <CMP Treatment>

The treatment liquid is used for an object to be treated, which has been subjected to the CMP treatment and contains the molybdenum (Mo)-containing substance. The object to be treated is preferably a semiconductor substrate which has been subjected to a CMP treatment.

The CMP treatment is a treatment in which a surface of the substrate having a layer selected from the metal wire film, the barrier metal, and the insulating film is flattened by a combined action of a chemical action and a mechanical polishing using a polishing slurry containing abrasive particles (abrasive grains).

A surface of the object to be treated which has been subjected to the CMP treatment may have residues such as abrasive grains (for example, silica and alumina) used in the CMP treatment, a polished metal wire film, and/or metal impurities (metal residue) derived from the barrier metal. In addition, an organic substance derived from a CMP treatment liquid used in the CMP treatment may remain as the residues. For example, since these residues may cause a short-circuit between wiring lines and deteriorate electrical characteristics of the semiconductor substrate, the semiconductor substrate which has been subjected to the CMP treatment is subjected to a cleaning treatment for removing these residues from the surface.

Specific examples of the object to be treated, which has been subjected to the CMP treatment, include substrates which have been subjected to the CMP treatment, described in Journal of the Japan Society for Precision Engineering, Vol. 84, No. 3, 2018, but the present invention is not limited thereto.

<Object to be Treated which has been Subjected to Pad Cleaning Treatment>

The surface of the object to be treated may be subjected to a pad cleaning treatment after the CMP treatment.

The pad cleaning treatment is a treatment of reducing residues present on the surface of the portion to be treated using a pad. Specifically, the surface of the object to be treated, which has been subjected to the CMP treatment, is brought into contact with the pad, and the object to be treated and the pad are relatively slid while supplying a composition for pad cleaning to a contact portion. As a result, the residues on the surface of the object to be treated are removed by a frictional force of the pad and the chemical action of the composition for pad cleaning.

The above-described pad is not particularly limited, and can be appropriately selected depending on the type of the object to be treated, the type of residues to be removed, and the device to be used. As the pad, a polishing pad used in the CMP treatment may be used, or a buff pad such as a foamed polyurethane-based buff pad, a nonwoven fabric, a suede-based buff pad, and a sponge may be used. The pad cleaning treatment using the pad includes a treatment called buff cleaning or buff polishing.

As the above-described composition for pad cleaning, a known cleaning composition can be used depending on the type of the object to be treated and the type and amount of the residues to be removed. Examples of components contained in the composition for pad cleaning include a water-soluble polymer such as polyvinyl alcohol, a dispersion medium such as water, and an acid such as nitric acid. In addition, the composition for pad cleaning does not contain abrasive particles.

The device and conditions used in the pad cleaning treatment can be appropriately selected from known devices and conditions depending on the type of the treatment object and the type and amount of the residues to be removed. For example, a treatment method described in paragraphs [0085] to [0088] of WO2017/169539A can be used, the contents of which are incorporated herein by reference.

In addition, as one embodiment of the pad cleaning treatment, it is also preferable to perform a pad cleaning treatment on the object to be treated, using the treatment liquid according to the embodiment of the present invention as the composition for pad cleaning.

The treatment liquid to be subjected to the pad cleaning treatment may be a diluted treatment liquid.

The pad cleaning treatment may be performed only once or may be performed twice or more. For example, after the CMP treatment, a pad cleaning treatment using a polishing pad and a pad cleaning treatment using a buff pad may be performed.

### [Cleaning Method of Object to be Treated]

The cleaning method of the object to be treated includes a cleaning step of cleaning the object to be treated, which has been subjected to the CMP treatment, using the above-described treatment liquid.

The treatment liquid to be used in the above-described cleaning step may be a diluted treatment liquid.

As the cleaning step of cleaning the object to be treated using the treatment liquid, a known cleaning method which is performed on the object to be treated which has been subjected to the CMP treatment can be used.

Examples of the cleaning method include a method of bringing the object to be treated into contact with the treatment liquid. The above-described contact method is not particularly limited; and examples thereof include a method of immersing the object to be treated in the treatment liquid contained in a tank, a method of spraying the treatment liquid onto the object to be treated, a method of flowing the treatment liquid onto the object to be treated, and a combination thereof. The above-described method may be appropriately selected depending on the purpose.

In addition, the above-described method may appropriately adopt a method usually performed in the field. For example, scrub cleaning in which a cleaning member such as a brush is physically brought into contact with a surface of the object to be treated while supplying the treatment liquid to remove residues and the like, spinning (dropping) cleaning in which the treatment liquid is dropped while rotating the object to be treated, or the like may be used. From the viewpoint that impurities remaining on a surface of the object to be treated can be further reduced, it is preferable that the object to be treated immersed in the treatment liquid is subjected to an ultrasonic treatment.

The above-described cleaning step may be performed once or twice or more. In a case of carrying out the cleaning twice or more, the same method may be repeated or different methods may be combined.

The cleaning method of the object to be treated may be a single-wafer method or a batch method. The single-wafer method is a method of treating one object to be treated at a time; and the batch method is a method of treating a plurality of objects to be treated at the same time.

A temperature of the treatment liquid in the cleaning step is not particularly limited, but from the viewpoint of defect removability, it is preferably 10° C. to 60° C., more preferably 15° C. to 50° C., and still more preferably 15° C. to 40° C.

It is preferable that a pH of the treatment liquid and a pH of the diluted treatment liquid are each in the above-described suitable aspect of pH.

A cleaning time in the cleaning step may be appropriately changed depending on the type, content, and the like of the components which can be contained in the treatment liquid, but is preferably 10 to 120 seconds, more preferably 20 to 90 seconds, and still more preferably 30 to 60 seconds.

A supply amount (supply rate) of the treatment liquid in the cleaning step is preferably 50 to 5,000 mL/min, and more preferably 500 to 2,000 mL/min.

In the cleaning step, a mechanical stirring method may be used in order to further improve the cleaning ability of the treatment liquid. Examples of the mechanical stirring method include a method of circulating the treatment liquid on the object to be treated, a method of flowing or spraying the treatment liquid on the object to be treated, and a method of stirring the treatment liquid with ultrasonic wave or megasonic wave.

After the cleaning step, a step of bringing the object to be treated into contact with a rinsing liquid (hereinafter, also referred to as “rinsing step”) may be performed. By performing the rinsing step, the object to be treated, obtained in the cleaning step, is washed with a rinsing liquid, and the residues can be efficiently removed.

The rinsing step is preferably a step which is carried out continuously subsequently after the cleaning step of the object to be treated, in which the object to be treated is rinsed with a rinsing liquid. The rinsing step may be performed using the above-described mechanical stirring method.

Examples of the rinsing liquid include water (preferably, DI water), methanol, ethanol, isopropyl alcohol (IPA), N-methylpyrrolidinone, 7-butyrolactone, dimethyl sulfoxide, ethyl lactate, and propylene glycol monomethyl ether acetate. In addition, an aqueous rinsing liquid having a pH of more than 8.0 (aqueous ammonium hydroxide which has been diluted, or the like) may be used.

As the method in which the rinsing liquid is brought into contact with the object to be treated, the method in which the treatment liquid is brought into contact with the object to be treated can be similarly applied.

A contact time between the object to be treated and the rinsing liquid can be appropriately changed depending on the type and content of each component contained in the treatment liquid, and the use target and purpose of the treatment liquid. The contact time is practically 10 to 120 seconds, preferably 20 to 90 seconds and more preferably 30 to 60 seconds.

A drying step of drying the object to be treated may be performed after the above-described rinsing step.

Examples of the drying method include a spin drying method, a method of flowing a dry gas onto the object to be treated, a method of heating a substrate by a heating unit such as a hot plate and an infrared lamp, a Marangoni drying method, a Rotagoni drying method, an isopropyl alcohol (IPA) drying method, and a method of combining any of these methods.

### [Method for Manufacturing Semiconductor Device]

The cleaning method for the object to be treated described above can be suitably applied to a method for manufacturing a semiconductor device.

The above-described cleaning method may be performed in combination before or after other steps performed on a substrate. The above-described cleaning method may be incorporated into other steps while performing the cleaning method, or the above-described cleaning method may be incorporated into the other steps.

Examples of the other steps include a step of forming each structure such as a metal wire, a gate structure, a source structure, a drain structure, an insulating film, a ferromagnetic layer, and a non-magnetic layer (for example, layer formation, etching, chemical mechanical polishing, modification, or the like), a resist forming step, an exposure step and a removal step, a heat treatment step, a cleaning step, and an examination step.

The above-described cleaning method may be performed at any stage among the back-end process (BEOL: back end of the line), the middle process (MOL: middle of the line), and the front-end process (FEOL: front end of the line); and it is preferable that the treatment method be performed in a front-end process or a middle process.

### EXAMPLES

Hereinafter, the present invention will be described in more detail with reference to Examples.

The materials, the amounts and proportions of the materials used, the details of treatments, the procedure of treatments, and the like shown in the following Examples can be appropriately modified as long as the gist of the present invention is maintained. Therefore, the scope of the present invention should not be construed as being limited to Examples shown below.

In the following Examples, a pH of the treatment liquid was measured at 25° C. using a pH meter (manufactured by HORIBA, Ltd., model “F-74”) in accordance with JIS Z 8802-1984.

In addition, in production of treatment liquids of Examples and Comparative Examples, all of handling of a container, and production, filling, storage, and analytical measurement of the treatment liquids were performed in a clean room satisfying a level of ISO Class 2 or lower.

### [Preparation of Treatment Liquid]

The following compounds were used to produce a treatment liquid. As various components used in Examples, those all classified into a semiconductor grade or a high-purity grade equivalent thereto were used.

### [Polymer (A) Having Sulfonic Acid Group]

PSSA-1: polystyrene sulfonic acid (weight-average molecular weight (MW)=8,000)
PSSA-2: polystyrene sulfonic acid (Mw=1,600)
PSSA-3: polystyrene sulfonic acid (Mw=5,000)
PSSA-4: polystyrene sulfonic acid (Mw=75,000, manufactured by FUJIFILM Wako Pure Chemical Corporation)
PSSA-5: polystyrene sulfonic acid (Mw=200,000)
PAMPs-1: poly(2-acrylamido-2-methyl-1-propanesulfonic acid) (Mw=800,000, manufactured by Sigma-Aldrich Co., LLC)
PAMPs-2: poly(2-acrylamido-2-methyl-1-propanesulfonic acid) (Mw=12,000)
   AA/AMPS: copolymer of acrylic acid (AA) and 2-acrylamido-2-methyl-1-propanesulfonic acid (AMPS) (AA:AMPS (molar ratio)=85:15) (Mw=8,500)
SSA/MA: copolymer of styrene sulfonic acid and maleic acid (molar ratio=1:1) (Mw=20,000)
PVSNa: poly(vinylsulfonic acid) sodium salt (Mw=5,000, manufactured by FUJIFILM Wako Pure Chemical Corporation)

### [Organic Acid (B) Having Hydroxy Group and Carboxy Group]

Citric acid
Tartaric acid
Malic acid
Lactic acid

### [Amino Acid (C)]

Arginine
Histidine
Lysine
Glycine

### [Other Additives]

DBS: dodecylbenzene sulfonic acid
PVPA: poly(vinyl phosphonic acid) (Mw=24,000, manufactured by FUJIFILM Wako Pure Chemical Corporation)
Sorbic acid
AA/MA: copolymer of acrylic acid and maleic acid (molar ratio=1:1) (Mw=3,000, manufactured by Sigma-Aldrich Co., LLC)
PA: polyacrylic acid (Mw=5,000, manufactured by TOAGOSEI CO., LTD.)
Trimellitic acid
Maleic acid
HEDP (ethidronic acid)
Oxalic acid
Hydrofluoric acid
Ammonium fluoride
IPA: isopropanol
EGBE: ethylene glycol monobutyl ether
Ammonia

The above-described compounds were mixed at mass ratios shown in Tables 1 and 2 to prepare a concentrated solution. Next, the above-described concentrated solution was diluted with ultrapure water as a diluent to have concentrations shown in Table 1 and Table 2, thereby obtaining treatment liquids of Examples and Comparative Examples, having formulations shown in Table 1 and Table 2.

A pH of the treatment liquids shown in Tables 1 and 2 was adjusted by adding at least one of a pH adjuster of trishydroxymethylaminomethane or sulfuric acid, as necessary.

In the treatment liquid, the remaining component (remainder) other than components specified as the components of the treatment liquid in the tables was ultrapure water and the pH adjuster. A content of the pH adjuster was 2% by mass or less in Examples 51 and 52, and 0.01% by mass or less in Examples other than Examples 51 and 52.

### <Measurement of Content of Sodium Atoms>

A content of sodium atoms in the treatment liquid prepared as described above was measured using Agilent 8900 triple quadrupole SNP-ICP/MS (for semiconductor analysis, Option #200).

### [Evaluation]

Using each treatment liquid of Examples or Comparative Examples prepared by the above-described method, the anticorrosion properties and the defect removability of the treatment liquid were evaluated by the following procedures.

### [Anticorrosion Properties]

The anticorrosion properties for molybdenum were evaluated using the treatment liquid prepared by the above-described method.

A molybdenum coupon wafer of 2×2 cm was prepared. The above-described wafer was placed in a container filled with the treatment liquid of each of Examples or each of Comparative Examples, and subjected to an immersion treatment at room temperature (25° C.) for 30 minutes. Thereafter, a film thickness of the wafer obtained using a resistivity meter (VR250, manufactured by Kokusai Electric Semiconductor Service Inc.) was measured, and an etching rate (Å/min) was determined from the difference in film thickness before and after the above-described immersion treatment.

The anticorrosion properties of the treatment liquid were evaluated according to the following evaluation standard. As the etching rate was lower, the anticorrosion properties were better. In practice, D or higher is preferable, and A is most preferable.

### (Evaluation Standard)

A: less than 0.4 Å/min
B: 0.4 Å/min or more and less than 0.6 Å/min
C: 0.6 Å/min or more and less than 0.8 Å/min
D: 0.8 Å/min or more and less than 1.0 Å/min
E: 1.0 Å/min or more

### [Defect Removability]

The defect removability in a case where an object to be treated, which had been subjected to the CMP treatment and contained a molybdenum-containing substance, was cleaned using the treatment liquid prepared by the above-described method was evaluated.

Using FREX300S-II (polishing device, manufactured by EBARA CORPORATION), a wafer (diameter: 12 inches) having a molybdenum film on the surface was polished under conditions of a polishing pressure of 2.0 psi (138 hPa), a polishing liquid supply rate of 0.28 mL/(min·cm²), and a polishing time of 60 seconds, using FSL3400C (product name, manufactured by Fujifilm Electronics Materials Co., Ltd.) to which 3% by mass of hydrogen peroxide was added as a polishing liquid.

Thereafter, the obtained wafer subjected to the CMP treatment was subjected to scrub cleaning for 60 seconds using the treatment liquid of each of Examples and Comparative Examples, adjusted to room temperature (23° C.), washed with deionized water for 30 seconds, and then subjected to a drying treatment.

A defect detection device (ComPlus-II, manufactured by AMAT) was used to measure the number of detections of signal intensities corresponding to defects having a length of more than 0.1 μm on the obtained polished surface of the wafer. As a result, the number of defects based on residues on the polished surface of the wafer was obtained.

The defect removability of the treatment liquid was evaluated according to the following evaluation standard. As the number of defects detected on the polished surface of the wafer was smaller, the cleanability was evaluated to be excellent. In practice, D or higher is preferable, and A is most preferable.

### (Evaluation Standard)

A: number of defects per wafer was less than 200.
B: number of defects per wafer was 200 or more and less than 300.
C: number of defects per wafer was 300 or more and less than 500.
D: number of defects per wafer was 500 or more and less than 1,000.
E: number of defects per wafer was 1,000 or more.

### [Result]

Table 1 and Table 2 show the formulation of each treatment liquid used in Examples and Comparative Examples, and the evaluation results of the treatment liquid.

In the tables, the column of “Added amount (% by mass)” indicates the content (% by mass) of each component with respect to the total mass of the treatment liquid.

In the tables, the numerical value in the column of “(B)/(A)” indicates the mass ratio of the content of the organic acid to the content of the polymer having a sulfonic acid group (Content of organic acid (B)/Content of polymer (A) having sulfonic acid group).

In the tables, the numerical value in the column of “(B)/(C)” indicates the mass ratio of the content of the organic acid to the content of the amino acid (Content of organic acid (B)/Content of amino acid (C)).

In the tables, the numerical value in the column of “(C)/(A)” indicates the mass ratio of the content of the amino acid to the content of the polymer having a sulfonic acid group (Content of amino acid (C)/content of polymer (A) having sulfonic acid group).

In the tables, the numerical value in the column of pH indicates the pH of the treatment liquid at 25° C., which was measured by the above-described pH meter.

TABLE 1

| | Formulation of treatment liquid | | | | | | | | | | | | | | |
|---|---|---|---|---|---|---|---|---|---|---|---|---|---|---|---|
| | Polymer having | | | | | | | | | | | | | Anti- | |
| | sulfonic acid | | Organic | | | Amino | | | | Other | | | | corro- | |
| | group (A) | | acid (B) | | | acid (C) | | | | additives | | | | sion | Defect |
| | | Added | | Added | | | Added | | | | Added | Na | | prop- | remov- |
| | | amount | | amount | | | amount | | | | amount | con- | | erties | ability |
| | | (% by | | (% by | (B)/ | | (% by | (B)/ | (C)/ | | (% by | tent | | Object | Object |
| | Type | mass) | Type | mass) | (A) | Type | mass) | (C) | (A) | Type | mass) | (ppb) | pH | Mo | Mo |
| Comparative | — | — | — | — | — | — | — | — | — | DBS | 0.005 | 3300 | 6.0 | D | E |
| Example 1 | | | | | | | | | | | | | | | |
| Comparative | — | — | — | — | — | — | — | — | — | Oxalic | 0.005 | <1 | 6.0 | E | E |
| Example 2 | | | | | | | | | | acid | | | | | |
| Comparative | — | — | — | — | — | — | — | — | — | PVPA | 0.005 | <1 | 6.0 | E | E |
| Example 3 | | | | | | | | | | | | | | | |
| Example 1 | PSSA-1 | 0.010 | — | — | — | — | — | — | — | — | — | <1 | 6.0 | D | D |
| Example 2 | PSSA-1 | 0.010 | Citric | 0.0050 | 0.5 | — | — | — | — | — | — | <1 | 6.0 | B | B |
| | | | acid | | | | | | | | | | | | |
| Example 3 | PSSA-2 | 0.010 | Citric | 0.0050 | 0.5 | — | — | — | — | — | — | <1 | 6.0 | B | B |
| | | | acid | | | | | | | | | | | | |
| Example 4 | PSSA-3 | 0.010 | Citric | 0.0050 | 0.5 | — | — | — | — | — | — | <1 | 6.0 | B | B |
| | | | acid | | | | | | | | | | | | |
| Example 5 | PSSA-4 | 0.010 | Citric | 0.0050 | 0.5 | — | — | — | — | — | — | <1 | 6.0 | B | C |
| | | | acid | | | | | | | | | | | | |
| Example 6 | PSSA-5 | 0.010 | Citric | 0.0050 | 0.5 | — | — | — | — | — | — | <1 | 6.0 | B | D |
| | | | acid | | | | | | | | | | | | |
| Example 7 | PAMPS-1 | 0.010 | Citric | 0.0050 | 0.5 | — | — | — | — | — | — | <1 | 6.0 | B | D |
| | | | acid | | | | | | | | | | | | |
| Example 8 | PAMPS-2 | 0.010 | Citric | 0.0050 | 0.5 | — | — | — | — | — | — | <1 | 6.0 | B | B |
| | | | acid | | | | | | | | | | | | |
| Example 9 | AA/ | 0.010 | Citric | 0.0050 | 0.5 | — | — | — | — | — | — | <1 | 6.0 | B | B |
| | AMPS | | acid | | | | | | | | | | | | |
| Example 10 | SSA/ | 0.010 | Citric | 0.0050 | 0.5 | — | — | — | — | — | — | <1 | 6.0 | B | B |
| | MA | | acid | | | | | | | | | | | | |
| Example 11 | PVSNa | 0.0010 | Citric | 0.0050 | 5 | — | — | — | — | — | — | 1600 | 6.0 | C | D |
| | | | acid | | | | | | | | | | | | |
| Example 12 | PSSA-1 | 0.010 | Tartaric | 0.0050 | 0.5 | — | — | — | — | — | — | <1 | 6.0 | B | B |
| | | | acid | | | | | | | | | | | | |
| Example 13 | PSSA-1 | 0.010 | Malic | 0.0050 | 0.5 | — | — | — | — | — | — | <1 | 6.0 | B | B |
| | | | acid | | | | | | | | | | | | |
| Example 14 | PSSA-1 | 0.010 | Lactic | 0.0050 | 0.5 | — | — | — | — | — | — | <1 | 6.0 | B | B |
| | | | acid | | | | | | | | | | | | |
| Example 15 | PSSA-1 | 0.00025 | Citric | 0.0050 | 20 | — | — | — | — | — | — | <1 | 6.0 | C | B |
| | | | acid | | | | | | | | | | | | |
| Example 16 | PSSA-1 | 0.00025 | Citric | 0.050 | 200 | — | — | — | — | — | — | <1 | 6.0 | D | C |
| | | | acid | | | | | | | | | | | | |
| Example 17 | PSSA-1 | 0.00025 | Citric | 0.10 | 400 | — | — | — | — | — | — | <1 | 6.0 | D | D |
| | | | acid | | | | | | | | | | | | |
| Example 18 | PSSA-1 | 0.0010 | Citric | 0.0050 | 5 | — | — | — | — | — | — | <1 | 6.0 | B | B |
| | | | acid | | | | | | | | | | | | |
| Example 19 | PSSA-1 | 0.010 | Citric | 0.00080 | 0.08 | — | — | — | — | — | — | <1 | 6.0 | B | C |
| | | | acid | | | | | | | | | | | | |
| Example 20 | PSSA-1 | 0.050 | Citric | 0.00080 | 0.016 | — | — | — | — | — | — | <1 | 6.0 | C | D |
| | | | acid | | | | | | | | | | | | |
| Example 21 | PSSA-1 | 0.050 | Citric | 0.00025 | 0.005 | — | — | — | — | — | — | <1 | 6.0 | D | D |
| | | | acid | | | | | | | | | | | | |
| Example 22 | PSSA-1 | 0.010 | Citric | 0.0050 | 0.5 | Arginine | 0.0050 | 1 | 0.5 | — | — | <1 | 6.0 | A | A |
| | | | acid | | | | | | | | | | | | |
| Example 23 | PSSA-1 | 0.010 | Citric | 0.0050 | 0.5 | Histidine | 0.0050 | 1 | 0.5 | — | — | <1 | 6.0 | A | A |
| | | | acid | | | | | | | | | | | | |
| Example 24 | PSSA-1 | 0.010 | Citric | 0.0050 | 0.5 | Lysine | 0.0050 | 1 | 0.5 | — | — | <1 | 6.0 | A | A |
| | | | acid | | | | | | | | | | | | |
| Example 25 | PSSA-1 | 0.010 | Citric | 0.0050 | 0.5 | Glycine | 0.0050 | 1 | 0.5 | — | — | <1 | 6.0 | B | A |
| | | | acid | | | | | | | | | | | | |

TABLE 2

| | Formulation of treatment liquid | | | | | | | |
|---|---|---|---|---|---|---|---|---|
| | Polymer having sulfonic | | | | | | | |
| | acid group (A) | | Organic acid (B) | | | Amino acid (C) | | |
| | | Added | | Added | | | Added | |
| | | amount | | amount | | | amount | |
| | | (% by | | (% by | (B)/ | | (% by | (B)/ |
| | Type | mass) | Type | mass) | (A) | Type | mass) | (C) |
| Example | PSSA-1 | 0.010 | Citric acid | 0.0050 | 0.5 | Arginine | 0.075 | 0.067 |
| 26 | | | | | | | | |
| Example | PSSA-1 | 0.010 | Citric acid | 0.0050 | 0.5 | Arginine | 1.0 | 0.0050 |
| 27 | | | | | | | | |
| Example | PSSA-1 | 0.010 | Citric acid | 0.0050 | 0.5 | Arginine | 3.0 | 0.0017 |
| 28 | | | | | | | | |
| Example | PSSA-1 | 0.010 | Citric acid | 0.0050 | 0.5 | Arginine | 0.00075 | 6.7 |
| 29 | | | | | | | | |
| Example | PSSA-1 | 0.010 | Citric acid | 0.0050 | 0.5 | Arginine | 0.00020 | 25 |
| 30 | | | | | | | | |
| Example | PSSA-1 | 0.010 | Citric acid | 0.0050 | 0.5 | Arginine | 0.00005 | 100 |
| 31 | | | | | | | | |
| Example | PSSA-1 | 0.010 | Citric acid | 0.0050 | 0.5 | — | — | — |
| 32 | | | | | | | | |
| Example | PSSA-1 | 0.010 | Citric acid | 0.0050 | 0.5 | — | — | — |
| 33 | | | | | | | | |
| Example | PSSA-1 | 0.010 | Citric acid | 0.0050 | 0.5 | — | — | — |
| 34 | | | | | | | | |
| Example | PSSA-1 | 0.010 | Citric acid | 0.0050 | 0.5 | — | — | — |
| 35 | | | | | | | | |
| Example | AA/AMPS | 0.010 | Citric acid | 0.0050 | 0.5 | Arginine | 0.0025 | 2 |
| 36 | | | | | | | | |
| Example | AA/AMPS | 0.010 | Citric acid | 0.0050 | 0.5 | Histidine | 0.0025 | 2 |
| 37 | | | | | | | | |
| Example | AA/AMPS | 0.010 | Citric acid | 0.0050 | 0.5 | Lysine | 0.0025 | 2 |
| 38 | | | | | | | | |
| Example | PSSA-1 | 0.010 | Citric acid | 0.0050 | 0.5 | Arginine | 0.0025 | 2 |
| 39 | | | | | | | | |
| Example | PSSA-1 | 0.010 | Citric acid | 0.0050 | 0.5 | Histidine | 0.0025 | 2 |
| 40 | | | | | | | | |
| Example | PSSA-1 | 0.010 | Citric acid | 0.0050 | 0.5 | Lysine | 0.0025 | 2 |
| 41 | | | | | | | | |
| Example | PSSA-1 | 0.010 | Citric acid | 0.0050 | 0.5 | Arginine | 0.0025 | 2 |
| 42 | | | | | | | | |
| Example | PSSA-1 | 0.010 | Citric acid | 0.0050 | 0.5 | Histidine | 0.0025 | 2 |
| 43 | | | | | | | | |
| Example | PSSA-1 | 0.010 | Citric acid | 0.0050 | 0.5 | Lysine | 0.0025 | 2 |
| 44 | | | | | | | | |
| Example | SSA/MA | 0.010 | Citric acid | 0.0050 | 0.5 | Arginine | 0.0025 | 2 |
| 45 | | | | | | | | |
| Example | SSA/MA | 0.010 | Citric acid | 0.0050 | 0.5 | Histidine | 0.0025 | 2 |
| 46 | | | | | | | | |
| Example | SSA/MA | 0.010 | Citric acid | 0.0050 | 0.5 | Lysine | 0.0025 | 25 |
| 47 | | | | | | | | |
| Example | PSSA-1 | 0.005 | Citric acid | 0.0050 | 0.5 | — | — | — |
| 48 | AA/AMPS | 0.005 | | | | | | |
| Example | PSSA-1 | 0.010 | Citric acid | 0.0050 | 0.5 | — | — | — |
| 49 | | | | | | | | |
| Example | PSSA-1 | 0.010 | Citric acid | 0.0025 | 0.5 | Lysine | 0.0025 | 1 |
| 50 | | | Tartaric | 0.0025 | | Glycine | 0.0025 | |
| | | | acid | | | | | |
| Example | PSSA-1 | 2.0 | Citric acid | 1.0 | 0.5 | — | — | — |
| 51 | | | | | | | | |
| Example | PSSA-1 | 2.0 | Citric acid | 1.0 | 0.5 | Lysine | 1.0 | 1 |
| 52 | | | | | | | | |

| | Formulation of treatment liquid | | | | | | |
|---|---|---|---|---|---|---|---|
| | | Other additives | | | | | |
| | | | Added | | | Anticorrosion | Defect |
| | | | amount | Na | | properties | removability |
| | (C)/ | | (% by | content | | Object | Object |
| | (A) | Type | mass) | (ppb) | pH | Mo | Mo |
| Example | 7.5 | — | — | <1 | 6.0 | A | B |
| 26 | | | | | | | |
| Example | 100 | — | — | <1 | 6.0 | B | C |
| 27 | | | | | | | |
| Example | 300 | — | — | <1 | 6.0 | C | D |
| 28 | | | | | | | |
| Example | 0.075 | — | — | <1 | 6.0 | B | A |
| 29 | | | | | | | |
| Example | 0.02 | — | — | <1 | 6.0 | B | A |
| 30 | | | | | | | |
| Example | 0.005 | — | — | <1 | 6.0 | B | B |
| 31 | | | | | | | |
| Example | — | — | — | <1 | 3.0 | B | C |
| 32 | | | | | | | |
| Example | — | — | — | <1 | 9.0 | C | B |
| 33 | | | | | | | |
| Example | — | — | — | <1 | 2.0 | B | D |
| 34 | | | | | | | |
| Example | — | — | — | <1 | 10.0 | D | B |
| 35 | | | | | | | |
| Example | 0.25 | Sorbic acid | 0.00025 | <1 | 6.0 | A | A |
| 36 | | | | | | | |
| Example | 0.25 | AA/MA | 0.001 | <1 | 6.0 | A | A |
| 37 | | | | | | | |
| Example | 0.25 | PA | 0.001 | <1 | 6.0 | A | A |
| 38 | | | | | | | |
| Example | 0.25 | Trimellitic | 0.001 | <1 | 6.0 | A | A |
| 39 | | acid | | | | | |
| Example | 0.25 | Maleic acid | 0.001 | <1 | 6.0 | A | A |
| 40 | | | | | | | |
| Example | 0.25 | HEDP | 0.001 | <1 | 6.0 | A | A |
| 41 | | | | | | | |
| Example | 0.25 | Oxalic acid | 0.001 | <1 | 6.0 | A | A |
| 42 | | | | | | | |
| Example | 0.25 | Hydrofluoric | 0.001 | <1 | 6.0 | A | A |
| 43 | | acid | | | | | |
| Example | 0.25 | Ammonium | 0.001 | <1 | 6.0 | A | A |
| 44 | | fluoride | | | | | |
| Example | 0.25 | IPA | 0.2 | <1 | 6.0 | A | A |
| 45 | | | | | | | |
| Example | 0.25 | IPA | 0.1 | <1 | 6.0 | A | A |
| 46 | | EGBE | 0.1 | | | | |
| Example | 0.25 | Ammonia | 0.2 | <1 | 6.0 | A | A |
| 47 | | | | | | | |
| Example | — | — | — | <1 | 6.0 | B | B |
| 48 | | | | | | | |
| Example | — | — | — | <1 | 6.0 | B | B |
| 49 | | | | | | | |
| Example | 0.5 | — | — | <1 | 6.0 | A | A |
| 50 | | | | | | | |
| Example | — | — | — | <1 | 6.0 | B | B |
| 51 | | | | | | | |
| Example | 0.5 | — | — | <1 | 6.0 | A | A |
| 52 | | | | | | | |

From the results of the tables, it was found that the treatment liquid according to the embodiment of the present invention was excellent in anticorrosion properties for molybdenum and excellent in defect removability on an object to be treated, in a case of being applied to cleaning of the object to be treated, which contained a molybdenum-containing substance and had been subjected to a chemical mechanical polishing treatment. On the other hand, the treatment liquids of Comparative Examples 1 and 2, which did not contain the polymer having a sulfonic acid group or a salt thereof, did not exhibit the above-described effects.

In addition, from the comparison of Examples 1 to 14, it was found that, in a case where the treatment liquid contained the organic acid having a hydroxy group and a carboxy group, the effect of the present invention was more excellent.

From the comparison between Examples 2 to 4 and 22 to 25, it was found that, in a case where the treatment liquid contained the amino acid, the effect of the present invention was more excellent.

From the comparison between Examples 2 and 15 to 17, it was found that, in a case where the mass ratio of the content of the organic acid having a hydroxy group and a carboxy group to the content of the polymer was 200 or less, the effect of the present invention is more excellent; in a case where the mass ratio was 50 or less, the effect of the present invention was further excellent; and in a case where the mass ratio was 5 or less, the effect of the present invention was particularly excellent.

From the comparison between Examples 2 and 19 to 21, it was found that, in a case where the mass ratio of the content of the organic acid having a hydroxy group and a carboxy group to the content of the polymer was 0.01 or more, the effect of the present invention was more excellent; in a case where the mass ratio was 0.05 or more, the effect of the present invention was further excellent; and in a case where the mass ratio was 0.10 or more, the effect of the present invention was particularly excellent.

From the comparison with Examples 22 to 28, it was found that, in a case where the mass ratio of the content of the amino acid to the content of the polymer was 200 or less, the effect of the present invention is more excellent; in a case where the mass ratio was 50 or less, the effect of the present invention was further excellent; and in a case where the mass ratio was 5 or less, the effect of the present invention was particularly excellent.

From the comparison between Examples 22 to 25 and 29 to 31, it was found that, in a case where the mass ratio of the content of the amino acid to the content of the polymer was 0.010 or more, the effect of the present invention was more excellent; and in a case where the mass ratio was 0.10 or more, the effect of the present invention was further excellent.

What is claimed is:

1. A treatment liquid used for cleaning an object to be treated, which contains a molybdenum-containing substance and has been subjected to chemical mechanical polishing, the treatment liquid comprising:
a polymer having a sulfonic acid group or a salt thereof; and
water.

2. The treatment liquid according to claim 1,
wherein the polymer further has a carboxy group or a salt thereof.

3. The treatment liquid according to claim 2,
wherein the polymer contains a repeating unit having a sulfonic acid group or a salt thereof and a repeating unit having a carboxy group or a salt thereof, and
a molar ratio C2/C1 of a content C2 of the repeating unit having a carboxy group or a salt thereof to a content C1 of the repeating unit having a sulfonic acid group or a salt thereof is 95/5 to 1/99.

4. The treatment liquid according to claim 1,
wherein a weight-average molecular weight of the polymer is 1,500 to 100,000.

5. The treatment liquid according to claim 1, further comprising:
an organic acid having a hydroxy group and a carboxy group.

6. The treatment liquid according to claim 5,
wherein a mass ratio of a content of the organic acid to a content of the polymer is 0.010 to 200.

7. The treatment liquid according to claim 1, further comprising:
an amino acid.

8. The treatment liquid according to claim 7,
wherein a mass ratio of a content of the amino acid to a content of the polymer is 0.010 to 200.

9. The treatment liquid according to claim 1,
wherein a content of sodium atoms is 1 ppm by mass or less with respect to a total mass of the treatment liquid.

10. The treatment liquid according to claim 1,
wherein a pH is 3.0 to 9.0.

11. A cleaning method for an object to be treated, comprising:
a step of cleaning an object to be treated, which contains a molybdenum-containing substance and has been subjected to chemical mechanical polishing, using the treatment liquid according to claim 1.

12. A method for manufacturing an electronic device, comprising:
the cleaning method for an object to be treated according to claim 11.

13. The treatment liquid according to claim 2,
wherein a weight-average molecular weight of the polymer is 1,500 to 100,000.

14. The treatment liquid according to claim 2, further comprising:
an organic acid having a hydroxy group and a carboxy group.

15. The treatment liquid according to claim 14,
wherein a mass ratio of a content of the organic acid to a content of the polymer is 0.010 to 200.

16. The treatment liquid according to claim 2, further comprising:
an amino acid.

17. The treatment liquid according to claim 16,
wherein a mass ratio of a content of the amino acid to a content of the polymer is 0.010 to 200.

18. The treatment liquid according to claim 2,
wherein a content of sodium atoms is 1 ppm by mass or less with respect to a total mass of the treatment liquid.

19. The treatment liquid according to claim 2,
wherein a pH is 3.0 to 9.0.

20. A cleaning method for an object to be treated, comprising:
a step of cleaning an object to be treated, which contains a molybdenum-containing substance and has been subjected to chemical mechanical polishing, using the treatment liquid according to claim 2.
